(19) United States
(12) Patent Application Publication
(10) Pub. No.: US 2002/0053700 A1
(43) Pub. Date: May 9, 2002

(54) SEMICONDUCTOR TRANSISTOR WITH MULTI-DEPTH SOURCE DRAIN

(76) Inventors: ARNE WATSON BALLANTINE, SOUTH BURLINGTON, VT (US); RAINER ERNST GEHRES, WALLKILL, NY (US); TERENCE BLACKWELL HOOK, JERICHO, VT (US); PETER SMEYS, WHITE PLAINS, NY (US)

Correspondence Address: RICHARD L CATANIA ESQ, SCULLY SCOTT MURPHY & PRESSER, 400 GARDEN CITY PLAZA, GARDEN CITY, NY, 11530

(21) Appl. No.: 09/363,355

(22) Filed: Jul. 29, 1999

(51) Int. Cl. H01L 31/119; H01L 31/113; H01L 31/062; H01L 29/94

(52) U.S. Cl. 257/344

(57) ABSTRACT

Methods for fabricating a semiconductor structure is provided wherein the diffusion region includes at least two regions of different depth, the deepest of which is aligned to the trench isolation region of the structure. Semiconductor structures such as FETs, resistors, bipolar transistors, capacitors and diodes comprising a semiconductor substrate having a surface; an external device region on the surface of said semiconductor substrate; a channel region of a first dopant type in said semiconductor substrate under said FET; and a doped region of a second dopant type in said substrate, said doped region comprising a first portion abutting said channel region, of a first depth, and a second portion abutting said first portion, of a second depth which is deeper than the depth of the first portion is also provided.

### FIELD OF THE INVENTION

The present invention relates to semiconductor device manufacturing, and in particular to a method of fabricating a semiconductor structure having at least one device region therein, such as a field effect transistor (FET), bipolar transistor, capacitor, resistor or diode. Specifically, the inventive structure comprises a silicide layer connecting diffusion regions of the structure to an external device region, wherein the diffusion regions of the structure contain at least two regions of different depth, with the deepest region being aligned to the trench isolation region and being formed underneath a recess/divot region of the structure. The structures of the present invention overcome leakage which normally occurs in prior art structures wherein a silicide layer is used to interconnect the diffusion regions to the external device region.

### BACKGROUND OF THE INVENTION

In order to form a low resistance contact to the source/drain regions of field effect transistors (FETs) and other semiconductor devices having a junction therein, a silicide layer is formed at the top surface of the semiconductor substrate. A typical structure of the kind mentioned above is shown for example in FIG. 1. Specifically, FIG. 1 is a cross-sectional view of a portion of a prior art structure comprising a semiconductor substrate 10 having a shallow trench isolation (STI) region 12 and a source/drain diffusion region 14 formed therein. A silicide layer 16 is formed on the surface of the semiconductor substrate 10 and it may be used to connect source/drain diffusion region 14 to an external device region which is not shown in FIG. 1.

During the manufacturing of these prior art structures, the STI fill material, e.g. SiO₂, may be etched back so that it is completely recessed lower than the surrounding semiconductor substrate or divotted lower at the STI and source/drain interface near the top surface of the wafer, or both. This allows an edge of the source/drain material to be exposed.

When the silicide layer is formed on the top of the source/drain diffusion region, it will also be formed on the exposed edge. This brings the silicide closer to the source/drain junction at the edges than in the center. Coupled to this is that the source/drain junction may tilt upward at the source/drain interface, and a relatively short path for potential leakage exists. In FIG. 1, both the STI recess and the divot are shown. Moreover, as illustrated in FIG. 1, the distance A is larger than the distance B, thus the potential for leakage exists.

In view of the potential leakage problem with prior art semiconductor structures, there exists a need for developing a new method which provides a structure wherein the distance B at the diffusion interface is sufficiently large so as to prevent leakage from occurring at this region of the structure.

### SUMMARY OF THE INVENTION

One object of the present invention is to provide a method of manufacturing a semiconductor structure wherein little or no leakage occurs at the area wherein the diffusion and STI regions meet, i.e. recess/divot region.

Another object of the present invention is to provide a method of fabricating a semiconductor structure wherein the diffusion region includes at least two regions of different depth, the deepest of which is aligned to the trench isolation region of the structure.

A still further object of the present invention is to provide a semiconductor structure wherein the deepest depth of the diffusion region is located underneath the recess/divot area of the structure.

These and other objects and advantages can be achieved in the present invention by providing a semiconductor structure where the diffusion region includes at least two regions of different depth, with the deepest depth being aligned to the junction between the STI and the diffusion region, i.e. underlying the recess/divot region of the semiconductor structure. It is noted that for simple junction devices such as diodes and resistors, the diffusion region will contain two regions of different depth. On the other hand for FET structures, the source/drain diffusion region may contain three regions of different depth. In each of these structures the deepest depth of the diffusion region is aligned to the trench isolation and diffusion junction.

In one aspect of the present invention, methods of forming the above mentioned semiconductor structures are provided. In accordance with one embodiment of the present invention, the method of the present invention comprises the steps of:

(a) providing a semiconductor structure having a recess, divot or both formed therein, said semiconductor structure further comprising at least a shallow trench isolation region and diffusion regions embedded in a semiconductor substrate;

(b) forming a masking material on the surface of the semiconductor substrate whereby the area at the diffusion regions and shallow trench isolation region is left exposed;

(c) providing a second region to said diffusion regions, wherein said second region has a deeper depth than the previous diffusion regions and is aligned with the shallow trench isolation region;

(d) removing the masking material; and

(e) forming a silicide layer on said semiconductor substrate so as to form a contact between the diffusion regions and any adjacent external device region.

The masking material employed in the present invention may be a resist, an inorganic dielectric such as SiO₂ or Si₃N₄, or both may be used. When both a resist and an inorganic dielectric are employed, the resist typically blocks the central region of the structure and an opening is formed in the inorganic dielectric over the area wherein the recess/divot is located.

In a second embodiment of the present invention, the method comprises the steps of:

(a) providing a semiconductor structure having a recess, divot or both therein, said structure further comprising at least a shallow trench isolation region and an extension embedded in a semiconductor substrate;

(b) forming a masking material on the surface of the structure whereby the area at the shallow trench isolation region and the extension is left exposed;

(c) doping through the exposed areas of the masking material, wherein said doping forms diffusion regions having at least two areas of different depth, the deepest of which is aligned to the trench isolation region;

(d) removing the masking material; and

(e) forming a silicide layer on said semiconductor substrate so as to form a contact between the diffusion regions and any adjacent external device region.

In another aspect of the present invention, a semiconductor structure is provided. Specifically, the structure of the present invention comprises:

a semiconductor substrate having a surface;

an external device region formed on the surface of said semiconductor substrate;

a channel region of a first dopant type in said semiconductor substrate under said device region;

a doped region of a second dopant type in said substrate, said doped region comprising a first portion abutting said channel region, of a first depth, and a second portion abutting said first portion, of a second depth which is deeper than the depth of the first portion; and

a silicide layer formed on said semiconductor substrate providing a contact between the doped region and the device region.

### BRIEF DESCRIPTION OF THE DRAWINGS

FIG. 1 is a cross-sectional view of a prior art semiconductor structure.

FIG. 2 is a cross-sectional view of a semiconductor structure of the present invention, including a FET as an external device region.

FIGS. 3A-C show the processing steps used in one embodiment of the present invention in fabricating the structure of FIG. 2.

FIGS. 4A-D show the processing steps used in a second embodiment of the present invention.

FIGS. 5A-D show the processing steps used in an alternative embodiment of the process depicted in FIGS. 4A-D.

FIGS. 6A-E show the processing steps used in a third embodiment of the present invention.

FIGS. 7A-B show: (A) a prior art FET structure; and (B) a FET structure of the present invention wherein the FET region is near the STI region.

FIGS. 8A-B show: (A) a prior art FET structure; and (B) a FET structure of the present invention wherein the STI region is spaced apart from the FET region.

FIGS. 9A-B show: (A) a prior art structure; and (B) a structure of the present invention wherein the diffusion region is bounded by STIs.

### DETAILED DESCRIPTION OF THE INVENTION

The present invention, which provides a novel semiconductor structure and methods of making the same, will now be described in greater detail by referring to the drawings that accompany the present invention. It is noted that like elements and/or components of the drawings are referred to by like reference numerals. It is also noted that the drawings of the present invention represent a fragment of the semiconductor structure of the present invention. The other half of the structure would look identical to the one depicted. It is further noted that although the drawings depict the presence of a FET region on the surface of the structure, the invention is not limited thereto. Other external devices like resistors, bipolar transistors, capacitors and diodes can be used in place of the FET shown in the drawings.

Referring to FIG. 2, there is shown one possible semiconductor structure that can be fabricated using the various methods of the present invention. Specifically, the structure shown in FIG. 2 comprises semiconductor substrate 10 having a shallow trench isolation (STI) region 12 and a source/drain diffusion region 14 formed therein. A recess/divot area 11 exists in the structure between the STI region and the source/drain diffusion region. The source/drain diffusion region comprises three regions of different depth, wherein the deepest depth is aligned with the STI and source/drain junction. The different depths are denoted as 14e (for the depth created by the extension), 14h (for the depth created by deep source/drain contacts) and 14v (for the depth created by the very deep implant step used in the present invention). The source/drain diffusion region may be of the n-type or the p-type depending on the type of dopant atoms used in the implant steps. Region 14e may or may not be present depending on the details of the external device design. For example, when the external device is a resistor or a diode, region 14e would not be present therein. In such case, the diffusion region would comprise two regions of different depths (14h and 14v), the deepest of which (14v) would be aligned as described above.

FIG. 2 also comprises FET region 22 which includes gate oxide 24, gate conductor 26 and, if present, sidewall isolation regions 28 formed on the sidewalls of the FET. The FET region is formed so that a portion thereof is in contact with the underlying source/drain diffusion region of the structure. A channel 15 is located underneath FET region 22, between the source and the drain regions. Again although illustration is made to a FET device, the invention embodied herein is no way limited to a FET structure. Other structures containing a device junction can be employed in the present invention, i.e. diodes, bipolar transistors, capacitors and resistors.

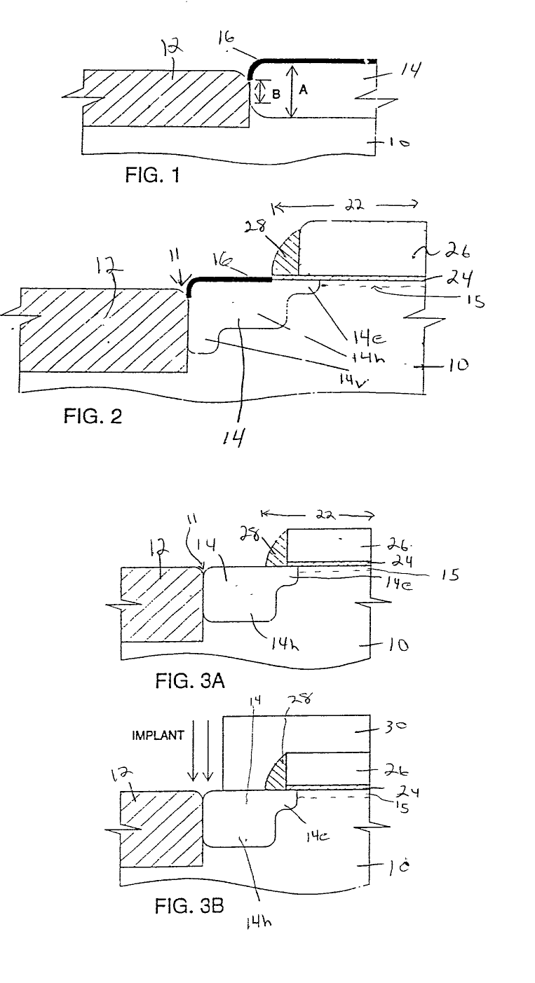

A silicide layer 16 is formed on the surface of the semiconductor substrate extending from the FET region to recess/divot area 11. It is noted that little or no leakage occurs at the recess/divot area of the inventive structure since the junction thereof contains a very deep implant whose distance is greater than that shown in FIG. 1.

The structure shown in FIG. 2 is composed of conventional materials that are well known to those skilled in the art. For example, semiconductor substrate 10 is composed of a conventional semiconducting material including, but not limited to: Si, Ge, GeSi, GaAs, InAs, InP and other III/V compounds. Of these semiconducting materials, it is preferred that semiconductor substrate 10 be composed of Si.

Shallow trench isolation region 12 is composed of a filler material such as silicon oxide or tetraethylorthosilicate (TEOS). FET region 22 is composed of a gate oxide 24 such as SiO₂ and a gate conductor 26 composed of doped polysilicon. The sidewall isolation regions are composed of conventional dielectric materials such as SiO₂ or Si₃N₄. The silicide layer is composed of TiSi₂, CoSi₂ or WSi₂.

The above describes one type of semiconductor structure of the present invention as well as the various components that make-up the same. The description that follows provides methods that can be used in the present invention for fabricating the structure of FIG. 2 as well as other structures wherein the FET region is replaced by a resistor or a diode or other like device.

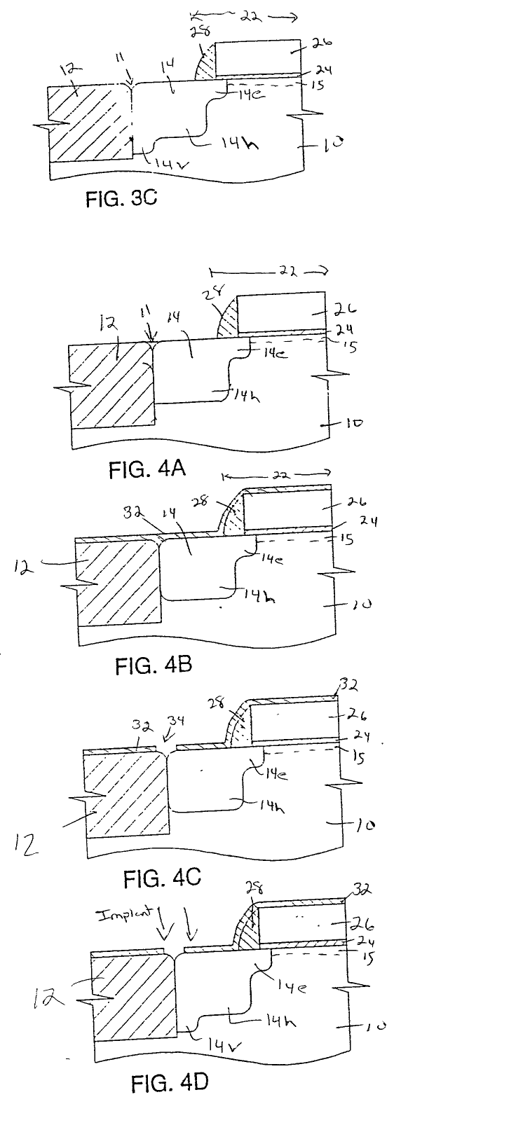

Referring first to FIGS. 3A-C, there is shown one embodiment of the present invention of fabricating the inventive FET structure shown in FIG. 2. In accordance with this method, an initial FET structure such as shown in FIG. 3A is first provided. The initial structure of FIG. 3A comprises semiconductor substrate 10, shallow trench isolation region 12, recess/divot area 11, FET region 22 and source/drain regions 14e and 14h. That is, the source/drain diffusion region includes an extension region (which is optional) and a deep source/drain contact region.

This initial FET structure shown in FIG. 3A is formed using conventional techniques well known to those skilled in the art. Since such techniques are well known, a detailed description is not needed herein. Instead, a brief description of one possible way of fabricating the initial structure is as follows: First, a trench for use in fabricating the STI region is formed in the surface of the semiconductor substrate using conventional lithography and reactive ion etching (RIE). The walls of the trench may be optionally covered with a barrier layer and thereafter the trench is filled with SiO₂ or tetraethylorthosilicate (TEOS). A directional deposition process is used in forming the optional barrier layer lining the walls of the trench whereas a conventional deposition process such as chemical vapor deposition, plasma-assisted chemical vapor deposition and sputtering is used to fill the trench. This structure is then recessed using standard etching processes or planarized using standard planarization techniques, e.g. chemical-mechanical polishing. These methods form a structure having a recess/divot therein.

Next, the gate region is formed by first providing a gate oxide on the semiconductor substrate. The gate oxide may be thermally grown or deposited using standard deposition techniques as mentioned above. A gate conductor is then formed on the surface of the gate oxide by conventional deposition techniques, e.g. chemical vapor deposition, and this gate stack, i.e. the gate oxide and gate conductor, is then patterned by conventional lithography and etching. When the gate conductor is polysilicon, doping may occur during the formation of the gate conductor, i.e. in-situ, or after patterning using conventional techniques well known to those in the art.

The portion of the source/drain diffusion region including the extension is then formed in the semiconductor substrate. Specifically, the source/drain extension, which is an optional region, is formed by using a conventional ion implantation apparatus operating at an ion dosage of from about 1×10¹⁴ to about 5×10¹⁴ atoms/cm². An optional Halo implant may be formed by ion implantation using an ion dosage of from about 1×10¹³ to about 1×10¹⁴ atoms/cm². The deep source/drain contact region 14h is formed by implantation using an ion dosage of from about 3×10¹⁵ to about 6×10¹⁵ atoms/cm². The sidewall spacers are then formed using a directional deposition process.

The depth of the optional extension, which extends from the surface of the semiconductor substrate, is less than about 150 nm. The optional Halo implant begins at the extension and extends to a depth of less than about 100 nm. The deep source/drain contact region has a depth that is less than about 200 nm below the surface of the semiconductor.

Next, as shown in FIG. 3B, a patterned resist 30 is provided on the structure so as to cover the FET region as well as a portion of the source/drain diffusion region. The patterned resist, however, does not cover the shallow trench isolation region, nor does it cover the recess/divot area of the FET structure. The patterned resist is a conventional resist material which is applied to the surface of the structure by standard deposition means, i.e. chemical vapor deposition, spin-on coating, dip coating and other like deposition techniques. The pattern is formed by pattern-wise exposure to radiation and development, both of which are well known to those skilled in the art.

Next, as also shown in FIG. 3B, the FET structure containing the patterned resist is then subjected to another ion implantation step. This ion implantation step which occurs at the junction between the STI region and the source/drain diffusion region is different from those mentioned above since it is a high energy implant step that is capable of forming another implant region in the structure which is deeper than the optional Halo implant region, the deep source/drain contact region or the optional extension region. Specifically, this high energy implant is carried out by ion implanting an appropriate dopant ion into the surface of the semiconductor substrate using ion implantation. The energies vary depending of the dopant species, but typically 10-20 KeV is employed when boron is the dopant species, and 20-30 KeV is employed when P is the dopant species. The dosage of the dopant ions implanted in this step of the present invention is from about 3×10¹⁵ to about 8×10¹⁵ atoms/cm².

The above conditions result in an implant which extends from the semiconductor substrate to a depth of less than about 300 nm.

The new implant region having the deepest depth is then thermally activated by annealing in an inert gas atmosphere at a temperature of from about 800° to about 1000° C. for a time period of from about 1 to about 10 seconds. It is emphasized that the new implant provides another region to the source/drain diffusion region which is aligned with the STI region and whose depth is greater than the other implants of the source/drain diffusion region. This structure, after resist removal, is shown in FIG. 3C.

Resist removal is carried out using conventional stripping techniques that are well known to those skilled in the art. For example, the resist can be removed using an oxygen plasma. After resist removal, a silicide layer 16 is formed on the surface of the semiconductor substrate so as to provide a contact between the FET region and the source/drain diffusion region, See FIG. 2. The silicide layer is formed using conventional techniques well known to those skilled in the art including: deposition of a metal layer and annealing to convert the metal into a silicide layer.

FIGS. 4A-D show another embodiment of the present invention which is similar to that shown in FIGS. 3A-C except that in place of resist 30, Si₃N₄ or another inorganic dielectric such as SiO₂ is employed as a masking material 32. In this embodiment of the present invention, the structure shown in FIG. 4A is first provided as described above for FIG. 3A. Next, a layer 32 of Si₃N₄ or SiO₂ is formed on the entire surface of the structure including STI region, semiconductor substrate and FET region. The masking layer is formed by standard deposition techniques including: chemical vapor deposition and plasma enhanced chemical vapor deposition.

Next, as shown in FIG. 4C, an opening 34 is provided in the masking layer so as to expose the area of the structure wherein recess/divot 11 is located. The very deep implant region 14v is then formed by a vapor phase doping process. After forming region 14v, masking layer 32 is removed by chemical etching, and then the silicide layer is formed as described above. This method also provides the structure shown in FIG. 2.

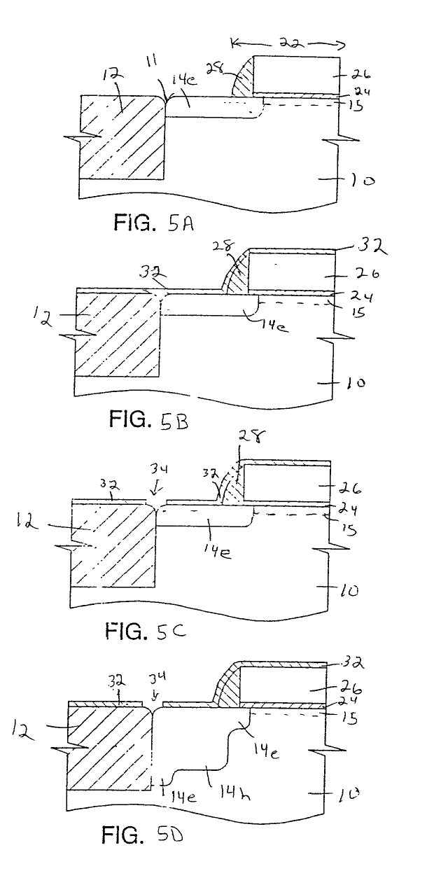

An alternative embodiment of the method illustrated in FIGS. 4A-D is shown in FIGS. 5A-D. In this embodiment of the present invention, the initial structure shown in FIG. 5A contains a source/drain extension and possibly an optional Halo implant region (not shown in the drawings). After forming the opening in masking layer 32, the source/drain implant is carried out so as to simultaneously provide two additional depths in the semiconductor substrate, 14h and 14v. Specifically, the deep source/drain contact region 14h is made shallower than the deepest implant region 14v of the present invention by the presence of film 32.

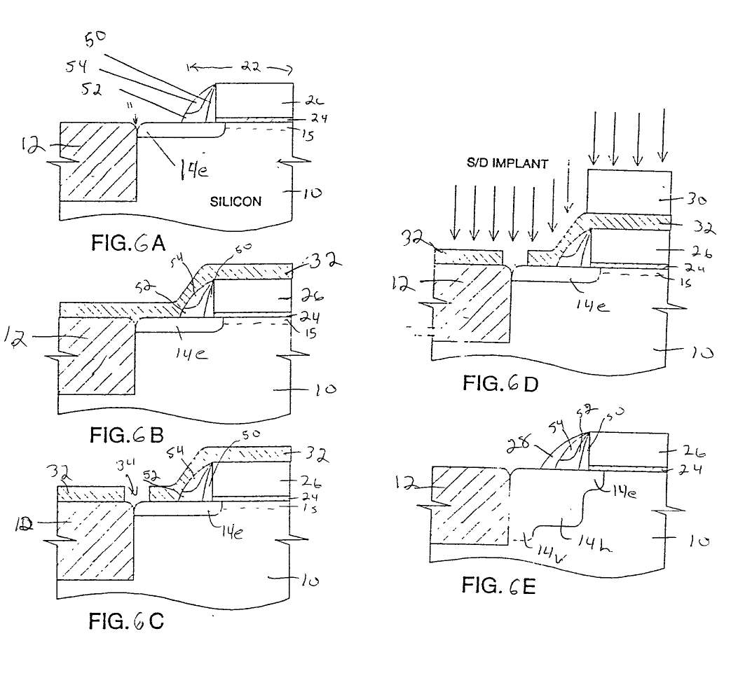

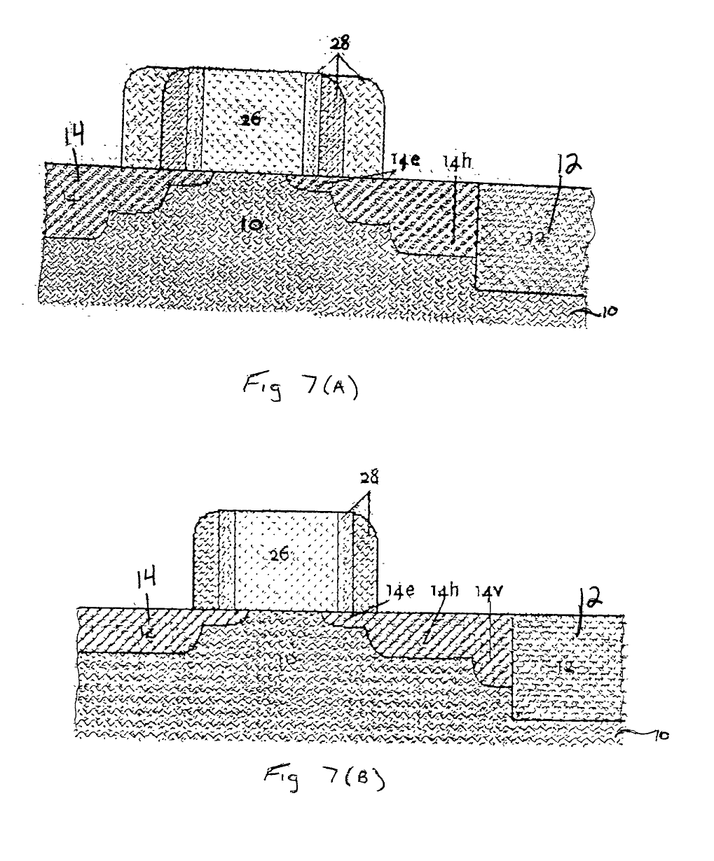

FIGS. 6A-E show another embodiment of the present invention. In accordance with this embodiment of the present invention, a structure as shown in FIG. 6A is first provided using conventional techniques well known to those skilled in the art. It is noted that the structure shown in FIG. 6A only includes a source/drain extension 14e; the deep source/drain contact region is not yet formed. This initial structure further includes a sidewall isolation region that comprises an oxide 50, nitride 52, TEOS 54 stack.

A layer of masking material 32 is then formed on the surface of the structure, See FIG. 6B, and patterned to form an opening at the recess/divot (FIG. 6C). A resist 30 is then formed on areas of masking layer 32 which are above the FET region. This structure is shown in FIG. 6D. The deep source/drain contact region and the very deep source/drain implant are then performed so as to produce a structure comprising a diffusion region having three different depths, the deepest of which is aligned to the STI region. The resist and the masking layer are then removed as shown in FIG. 6E and sidewall isolation region 28 is then formed over the oxide/nitride/TEOS stack. Thereafter, the silicide layer is formed on the surface of the structure as shown in FIG. 2.

It is again noted that the presence of an FET is in no way limiting to this invention, and that the techniques described above for reducing leakage are equally applicable to other simple junctions commonly found in semiconductor circuits, such as resistors, bipolar transistors, capacitors and diodes. For those simple junctions, the techniques of the present invention form two regions in the diffusion region, the deepest depth being aligned to the STI region as mentioned above.

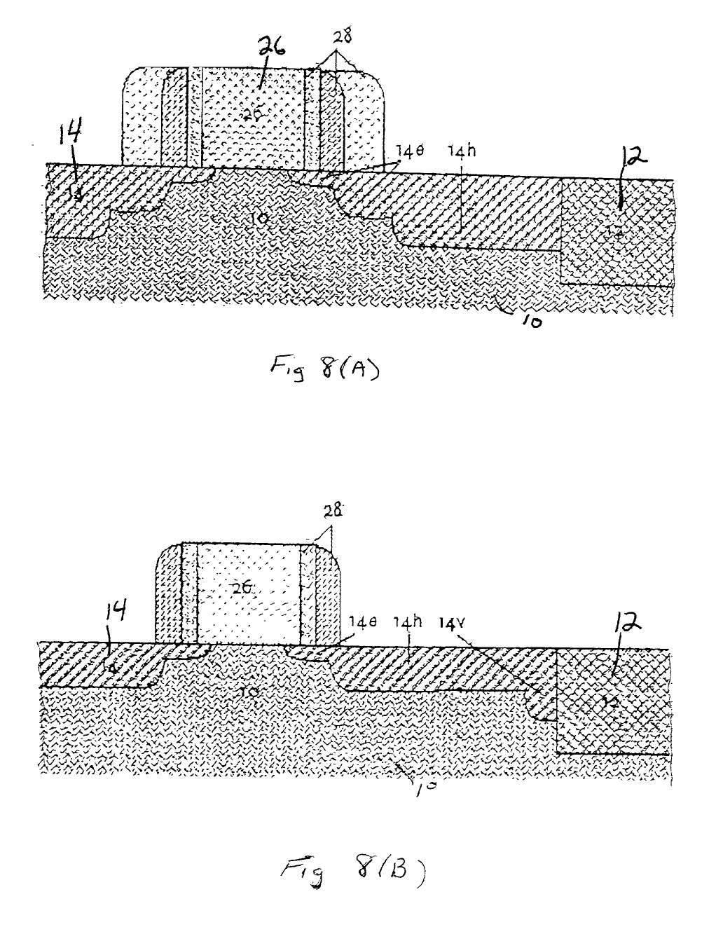

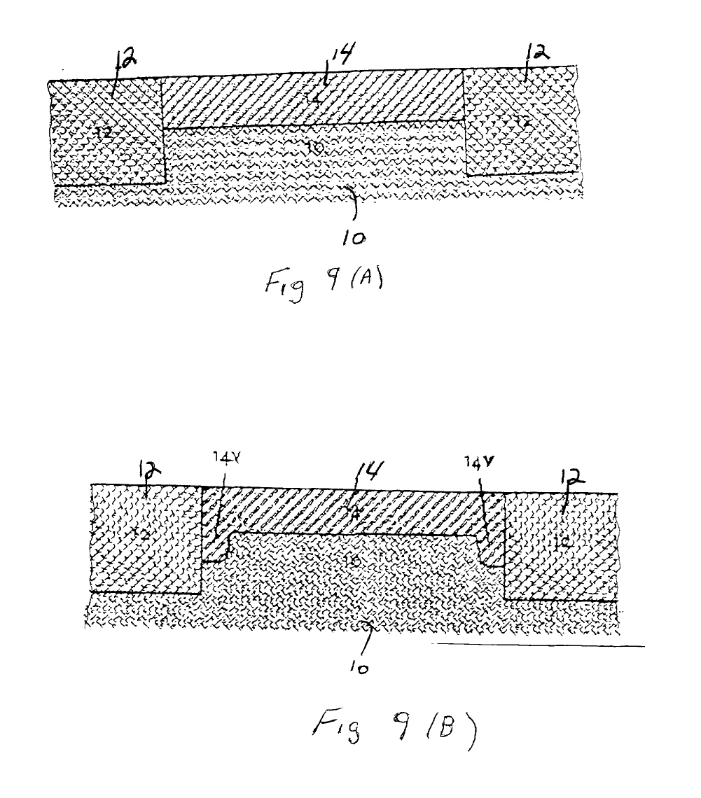

FIGS. 7-9 illustrate the difference between the structures of the present invention (FIGS. 7B, 8B and 9B) and the structures of the prior art (FIGS. 7A, 8A and 9A).

In the prior art, diffusion depths are aligned to the edges of the MOSFET gate 26. Spacer films 28 are used to space diffusions 14 of different depths 14e and 14h to different widths or positions. However, these diffusions are still aligned to gate 26. Therefore, when the distance between gate 26 and shallow trench isolation (STI) 12 changes, diffusions 14 change in position with respect to the position of gate 26, not with respect to the position of STI 12. And, in a region where a diffusion 14 only is present, no different diffusion depths are created.

In the invention, a deeper diffusion region 14v is created which is aligned to STI 12. Therefore, when the distance between gate 26 and STI 12 changes, the position of this deep diffusion 14v stays aligned to the position of STI 12. And, in a region where only a diffusion 14 is present, deep diffusions 14v adjacent and aligned to the STI 12 are created.

While the present invention has been particularly shown and described with respect to the preferred embodiments thereof, it will be understood by those skilled in the art that the foregoing and other changes in form and details may be made therein without departing from the spirit and scope of the present invention. It is therefore intended that the present invention not be limited to the exact forms described and illustrated, but fall within the scope of the appended claims.

Having thus described our invention in detail, what we claim as new and desire to secure by the Letters Patent is:

1. A method of fabricating a semiconductor structure, wherein said structure comprises diffusion regions having at least two regions of different depth, the deepest of which is aligned to an adjacent trench isolation region, said method comprising the steps of:
(a) providing a semiconductor structure having a recess, divot or both formed therein, said structure further comprising at least a shallow trench isolation region and a diffusion region embedded in a semiconductor substrate;
(b) forming a masking material on the surface of the semiconductor substrate whereby the area at the diffusion region and shallow trench isolation junction is left exposed;
(c) providing a second region to said diffusion region, wherein said second region has a deeper depth than the previous diffusion region and is aligned to the shallow trench isolation region;
(d) removing the masking material; and
(e) forming a silicide layer on said semiconductor substrate so as to form a contact between the diffusion region and any adjacent external device region.

2. A method of fabricating a semiconductor structure wherein said structure comprises a diffusion region having at least two regions of different depth, the deepest of which is aligned to an adjacent trench isolation region, said method comprising the steps of:
(a) providing a semiconductor structure having a recess, divot or both formed therein, said FET structure further comprising at least a shallow trench isolation region and an extension embedded in a semiconductor substrate;
(b) forming a masking material on the surface of the structure whereby the area at the shallow trench isolation region and the extension is left exposed;
(c) doping through the exposed areas of the masking material, wherein said doping forms a diffusion region having at least two areas of different depth, the deepest of which is aligned to the shallow trench isolation;
(d) removing the masking material; and
(e) forming a silicide layer on said semiconductor substrate so as to form a contact between the diffusion region and any adjacent external device region.

3. The method of claim 1 wherein said semiconductor substrate is composed of Si, Ge, GeSi, GaAs, InAs, InP or another III/V compound.

4. The method of claim 3 wherein said semiconductor substrate is composed of Si.

5. The method of claim 1 wherein said masking material is a resist, SiO₂, Si₃N₄ or any combination thereof.

6. The method of claim 1 wherein said diffusion region provided in (a) comprises an optional extension region, a deep contact region and an optional Halo implant region.

7. The method of claim 6 wherein said optional extension region is formed using an ion implantation apparatus operating at an ion dosage of from about 1×10¹⁴ to about 5×10¹⁴ atoms/cm².

8. The method of claim 6 wherein said optional Halo implant is formed using an ion implantation apparatus operating at an ion dosage of from about 1×10¹³ to about 1×10¹⁴ atoms/cm².

9. The method of claim 6 wherein said deep contact region is formed using an ion implantation apparatus operating at an ion dosage of from about 3×10¹⁵ to about 6×10¹⁵ atoms/cm².

10. The method of claim 1 wherein said second region is formed using a high energy ion implantation process or a vapor phase doping process.

11. The method of claim 9 wherein said high energy ion implantation step is carried out at an ion dosage of from about 3×10¹⁵ to about 8×10¹⁵ atoms/cm².

12. The method of claim 1 wherein said external device region is a resistor, diode, bipolar transistor, capacitor or a field effect transistor (FET).

13. The method of claim 2 wherein said extension region is formed using an ion implantation apparatus operating at an ion dosage of from about 1×10¹⁴ to about 5×10¹⁴ atoms/cm².

14. The method of claim 2 wherein step (c) includes a deep diffusion contact formation step and a high energy ion implantation or vapor phase doping step.

15. The method of claim 14 wherein said deep diffusion contact formation step is carried out using an ion implantation apparatus operating at an ion dosage of from about 3×10¹⁵ to about 6×10¹⁵ atoms/cm².

16. The method of claim 14 wherein said high energy ion implantation step is carried out at an ion dosage of from about 3×10¹⁵ to about 8×10¹⁵ atoms/cm².

17. The method of claim 2 wherein an optional Halo implant region is present in the structure.

18. The method of claim 2 wherein said masking material is a resist, SiO₂, Si₃N₄ or any combination thereof.

19. The method of claim 2 wherein said external device region is a resistor, diode, bipolar transistor, capacitor or a field effect transistor.

20. A semiconductor structure comprising:
a semiconductor substrate having a surface;
an external device region on the surface of said semiconductor substrate;
a channel region of a first dopant type in said semiconductor substrate under said FET; and
a doped region of a second dopant type in said substrate, said doped region comprising a first portion abutting said channel region, of a first depth, a second portion abutting said first portion, of a second depth which is deeper than the depth of the first portion.

21. The semiconductor structure of claim 20 further comprising other portions whose depths are shallower than the second portion of said doped region.

22. The semiconductor structure of claim 20 wherein said semiconductor substrate is composed of Si, Ge, GeSi, GaAs, InAs, InP or another III/V compound.

23. The semiconductor structure of claim 22 wherein said semiconductor substrate is composed of Si.

24. The semiconductor structure of claim 20 wherein said external device region is a FET region, a diode, bipolar transistor, capacitor or a resistor.

25. The semiconductor structure of claim 20 wherein said FET region comprises a gate oxide, a gate conductor and, optionally, sidewall spacers.

26. The semiconductor structure of claim 25 further comprising a oxide/TEOS/nitride stack formed on sidewalls of said FET prior to forming said sidewall spacers.

27. The semiconductor structure of claim 20 wherein said first portion of said doped region is a diffusion contact region.

28. The semiconductor structure of claim 27 wherein said diffusion contact region extends from said surface of said semiconductor substrate to a depth of less than about 200 nm.

29. The semiconductor structure of claim 20 wherein said second portion is a very deep implant region that extends from the semiconductor substrate to a depth less than about 300 nm.

30. The semiconductor structure of claim 21 wherein said other portions include an extension region and a Halo implant region.

31. The semiconductor structure of claim 30 wherein said extension region extends from said semiconductor substrate to a depth of less than about 150 nm.

32. The semiconductor structure of claim 30 wherein said Halo implant region begins at said extension and extends to a depth of less than 100 nm.
